(19) United States
(12) Patent Application Publication
(10) Pub. No.: US 2018/0286997 A1
(43) Pub. Date: Oct. 4, 2018

(54) ENCAPSULANT FOR SOLAR CELLS AND SOLAR CELL MODULE COMPRISING THE SAME

(71) Applicant: SKC CO., LTD., Suwon-si (KR)

(72) Inventors: Gun Uk KIM, Anyang-si (KR); Kweon Hyung HAN, Suwon-si (KR)

(73) Assignee: SKC CO., LTD., Suwon-si (KR)

(21) Appl. No.: 15/936,591

(22) Filed: Mar. 27, 2018

(30) Foreign Application Priority Data
Mar. 30, 2017 (KR) 10-2017-0040515
Dec. 19, 2017 (KR) 10-2017-0174810

(51) Int. Cl. H01L 31/048; C08K 3/22; C08K 5/14; C08K 5/3492

(52) U.S. Cl. CPC H01L 31/0481; C08K 3/22; C08K 2201/006; C08K 5/34924; C08K 2003/222; C08K 5/14

(57) ABSTRACT

Embodiments relate to an encapsulant for solar cells and a solar cell module comprising the same. The encapsulant for solar cells is excellent in moisture resistance and durability since it adsorbs acetic acid that is generated from an ethylene-vinyl acetate copolymer. Therefore, the solar cell module comprising the encapsulant for solar cells can minimize a reduction in the power output even when it is exposed to the exterior for a long period of time.

### TECHNICAL FIELD

Embodiments relate to an encapsulant for solar cells, which is excellent in durability and moisture resistance, so that it can minimize a reduction in the power output of the solar cells, and a solar cell module comprising the same.

### BACKGROUND ART

An ethylene-vinyl acetate copolymer has been widely used as an encapsulant for solar cell modules. However, an ethylene-vinyl acetate copolymer has a problem that acetic acid is generated due to hydrolysis of the copolymer when it is exposed to the exterior for a long period of time. In particular, the acetic acid thus generated causes a problem that it corrodes the electrodes of a solar cell module, thereby shortening the lifetime of the solar cell module. Therefore, many researchers have made great efforts to control the generation of acetic acid from an ethylene-vinyl acetate copolymer.

As the most fundamental solution, a method of employing a polyolefin as an encapsulant for a solar cell module instead of an ethylene-vinyl acetate copolymer has been proposed (Korean Laid-open Patent Publication No. 2009-0096487). However, a polyolefin is less heat resistant than an ethylene-vinyl acetate copolymer, and there has been a restriction for a polyolefin encapsulant to be commercialized because of its high price.

In addition, Japanese Patent Nos. 5819159 and 5820132 disclose a method of mixing an ethylene-vinyl acetate copolymer with an ethylene methacrylic acid copolymer. However, the effect of suppressing the generation of acetic acid is not ensured, and the mixing of two or more kinds of resins may give rise to difficulties in the process.

Further, Japanese Patent No. 4863812 discloses a method of employing a carbodiimide compound as an anti-hydrolysis agent in order to suppress the generation of acetic acid from an ethylene-vinyl acetate copolymer. However, the anti-hydrolysis agent involves a problem that yellowing of the encapsulant occurs.

### DISCLOSURE OF THE INVENTION

### Technical Problem

Accordingly, an embodiment aims to provide an encapsulant for solar cells, which is excellent in durability by way of suppressing the generation of acetic acid from an ethylene-vinyl acetate copolymer, so that it is possible to minimize a reduction in the power output of the solar cells and shortening of the lifetime thereof, and a solar cell module comprising the same.

### Solution to the Problem

An embodiment to achieve the above object provides an encapsulant for solar cells, which comprises an ethylene-vinyl acetate copolymer and magnesium oxide, wherein the magnesium oxide is contained in an amount of 0.001 to 0.20 parts by weight based on 100 parts by weight of the ethylene-vinyl acetate copolymer and has a specific surface area of 50 to 200 m²/g.

Another embodiment provides a solar cell module, which comprises a transparent protective substrate, a first encapsulant sheet, at least one solar cell connected to an electrode, a second encapsulant sheet, and a back sheet, all of which are laminated in this order, wherein at least one of the first encapsulant sheet and the second encapsulant sheet comprises an ethylene-vinyl acetate copolymer and magnesium oxide, and the magnesium oxide is contained in an amount of 0.001 to 0.20 parts by weight based on 100 parts by weight of the ethylene-vinyl acetate copolymer and has a specific surface area of 50 to 200 m²/g.

Still another embodiment provides a process for preparing an encapsulant for solar cells, which comprises (1) mixing an ethylene-vinyl acetate copolymer and magnesium oxide to prepare a masterbatch; (2) mixing the masterbatch with an ethylene-vinyl acetate copolymer to prepare an encapsulant composition; and (3) melt-extruding the encapsulant composition, wherein the magnesium oxide is contained in the encapsulant composition in an amount of 0.001 to 0.20 parts by weight per 100 parts by weight of the ethylene-vinyl acetate copolymer and has a specific surface area of 50 to 200 m²/g.

### Advantageous Effects of the Invention

The encapsulant for solar cells according to the embodiments is excellent in moisture resistance and durability since it adsorbs acetic acid that is generated from an ethylene-vinyl acetate copolymer. Therefore, a solar cell module comprising the encapsulant for solar cells can minimize a reduction in the power output even when it is exposed to the exterior for a long period of time.

### BRIEF DESCRIPTION OF THE DRAWINGS

FIGS. 1 and 2 schematically illustrate the configurations (i.e., an exploded view and an assembled view, respectively) of a solar cell module according to an embodiment, which comprises solar cells and encapsulant sheets.

### BEST MODE FOR CARRYING OUT THE INVENTION

Hereinafter, the present invention will be described in detail with reference to the embodiments. The embodiments are not limited to those described below and may be modified into various forms as long as the gist of the invention is not altered.

Throughout the description of the embodiments, in the case where each film, window, panel, layer, or the like is mentioned to be formed “on” or “under” another film, window, panel, layer, or the like, it means not only that one element is directly formed on or under another element, but also that one element is indirectly formed on or under another element with other element(s) interposed between them. Also, the term “on” or “under” with respect to each element may be referenced to the drawings. For the sake of description, the sizes of individual elements in the appended drawings may be exaggeratingly depicted and do not indicate the actual sizes. Further, the same reference numeral refers to the same element throughout the specification.

In this specification, when a part is referred to as “comprising” an element, it is to be understood that the part may comprise other elements as well, unless otherwise indicated.

Further, all numbers and expression related to the quantities of components, reaction conditions, and the like used herein are to be understood as being modified by the term “about,” unless otherwise indicated.

Encapsulant for Solar Cells

According to an embodiment, there is provided an encapsulant for solar cells, which comprises an ethylene-vinyl acetate copolymer and magnesium oxide, wherein the magnesium oxide is contained in an amount of 0.001 to 0.20 parts by weight based on 100 parts by weight of the ethylene-vinyl acetate copolymer and has a specific surface area of 50 to 200 m²/g.

Ethylene-Vinyl Acetate Copolymer

The ethylene-vinyl acetate copolymer may comprise 20 to 35% by weight of vinyl acetate based on the total weight of the copolymer. Specifically, the ethylene-vinyl acetate copolymer may comprise 20 to 33% by weight, 25 to 33% by weight, or 26 to 33% by weight of vinyl acetate based on the total weight of the copolymer. If the content of vinyl acetate is within the above range, the copolymer has the effects of excellent processability into a sheet and excellent performance in protecting the cells as an encapsulant for solar cells.

The ethylene-vinyl acetate copolymer may have a melt flow rate (MFR) of 5 to 30 g/10 min at 190° C. under a load of 2.16 kg. Specifically, the ethylene-vinyl acetate copolymer may have a melt flow rate (MFR) of 5 to 25 g/10 min, 5 to 20 g/10 min, or 10 to 20 g/10 min at 190° C. under a load of 2.16 kg. If the melt flow rate of the ethylene-vinyl acetate copolymer is within the above range, it is possible to stably form a sheet without the problems that the extrusion of the copolymer is not readily performed due to a low flowability and that the copolymer flows out in the lamination step to contaminate the equipment due to an excessively high flowability.

The ethylene-vinyl acetate copolymer may have a weight average molecular weight of 10,000 to 100,000 g/mole. Specifically, the copolymer may have a weight average molecular weight of 20,000 to 60,000 g/mole, 30,000 to 60,000 g/mole, or 50,000 to 60,000 g/mole.

Magnesium Oxide

The magnesium oxide is contained in an amount of 0.001 to 0.20 parts by weight based on 100 parts by weight of the ethylene-vinyl acetate copolymer. Specifically, the magnesium oxide may be contained in an amount of 0.005 to 0.10 parts by weight, 0.009 to 0.07 parts by weight, 0.01 to 0.20 parts by weight, or 0.01 to 0.15 parts by weight, based on 100 parts by weight of the ethylene-vinyl acetate copolymer. If the content of magnesium oxide is within the above range, the magnesium oxide is uniformly dispersed in the encapsulant to thereby readily adsorb acetic acid, and it is possible to prevent the problems that the power output of the solar cell module is reduced by impairing the light transmittance of the encapsulant and that the degree of crosslinking of the encapsulant is reduced by retarding the crosslinking reaction of the ethylene-vinyl acetate copolymer.

In addition, the magnesium oxide has a specific surface area of 50 to 200 m²/g. Specifically, the magnesium oxide may have a specific surface area of 70 to 200 m²/g, 90 to 200 m²/g, or 100 to 200 m²/g. The magnesium oxide may have different capabilities in adsorbing acetic acid depending on the specific surface area thereof. If the specific surface area of the magnesium oxide is within the above range, it is possible to prevent the problems that the capability of adsorbing acetic acid is reduced by impairing the reactivity thereof and that the degree of crosslinking of the encapsulant is reduced by retarding the crosslinking reaction of the ethylene-vinyl acetate copolymer. In particular, as described above, since the magnesium oxide of the embodiment has a large specific surface area, the desired capability of adsorbing acetic acid can be achieved even if a small amount thereof is used. Therefore, it is possible to further improve the durability of the encapsulant for solar cells thus prepared by suppressing the generation of acetic acid while the side effects that may occur due to an excessive use of magnesium oxide are reduced.

Most substances that adsorb acids other than the above-mentioned magnesium oxide also have a characteristic of adsorbing moisture. For example, zeolite or silica has a property of adsorbing acids like magnesium oxide. Thus, if it is employed in an encapsulant for solar cells, it can produce a similar effect of adsorbing acetic acid. But it has a disadvantage of adsorbing moisture as well as acetic acid. Thus, if zeolite or silica is employed in an encapsulant instead of magnesium oxide, the encapsulant adsorbs moisture under harsh conditions, resulting in problems that the volume resistivity of the encapsulant decreases and that the resistance to wet leakage thereof deteriorates. In contrast, since magnesium oxide does not adsorb moisture, it does not give rise to the above-mentioned problems even under harsh conditions.

The magnesium oxide may have an average diameter of 1 to 20 μm. Specifically, the magnesium oxide may have an average diameter of 2 to 20 μm, 2 to 15 μm, or 2 to 10 μm.

The magnesium oxide may have an appropriate particle size distribution. For example, the magnesium oxide may contain particles having a particle diameter smaller than the average particle diameter by 2.5 μm or more in an amount of 5 to 15% by weight based on the total weight of the magnesium oxide. In addition, the magnesium oxide may contain particles having a particle diameter larger than the average particle diameter by 6.5 μm or more in an amount of 5 to 15% by weight based on the total weight of the magnesium oxide. If the magnesium oxide has a particle size distribution as described above, the durability of the encapsulant for solar cells thus prepared can be improved.

Crosslinking Agent

The encapsulant for solar cells may comprise an organic peroxide as a crosslinking agent. The organic peroxide serves to improve the weatherability of the encapsulant for solar cells.

The crosslinking agent is not particularly limited as long as it is an organic peroxide capable of generating radicals at 100° C. or higher. But it preferably has a half-life of 10 hours or longer and a decomposition temperature of 70° C. or higher in consideration of the stability during compounding. The lower the half-life temperature, the faster the reactivity. The higher the half-life temperature, the slow the reactivity.

Specifically, the organic peroxide may be at least one selected from the group consisting of 2,5-dimethylhexane-2,5-dihydroperoxide, 2,5-dimethyl-2,5-di(t-butylperoxy)hexane, di-t-butyl peroxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)-3,3,5-trimethylcyclohexane, t-butyl peroxybenzoate, benzoyl peroxide, and t-butylperoxy-2-ethylhexyl carbonate.

The crosslinking agent may be contained in an amount of 5 parts by weight or less based on 100 parts by weight of the ethylene-vinyl acetate copolymer. Specifically, the crosslinking agent may be contained in an amount of 0.3 to 5 parts by weight, or 0.3 to 2 parts by weight, based on 100 parts by weight of the ethylene-vinyl acetate copolymer.

Crosslinking Aid

The encapsulant for solar cells may comprise a crosslinking aid. The crosslinking aid serves to improve the gel fraction of the ethylene-vinyl acetate copolymer and to improve the durability of the encapsulant.

The crosslinking aid may be contained in an amount of 10 parts by weight or less based on 100 parts by weight of the ethylene-vinyl acetate copolymer. Specifically, the crosslinking aid may be contained in an amount of 0.1 to 10 parts by weight, 0.1 to 5 parts by weight, or 0.1 to 3 parts by weight, based on 100 parts by weight of the ethylene-vinyl acetate copolymer.

Examples of the crosslinking aid include compounds having three functional groups such as triallyl isocyanurate, triallyl isocyanate, and the like, and compounds having one functional group such as an ester and the like.

Additive

The encapsulant for solar cells may further comprise an additive selected from the group consisting of a silane coupling agent, a quinone-based compound, an ultraviolet absorber, an antioxidant, and a discoloration inhibitor.

The silane coupling agent serves to improve the adhesion between the encapsulant and the solar cells. The silane coupling agent may be, for example, γ-chloropropyltrimethoxysilane, vinyltrichlorosilane, vinyl-tris-(β-methoxyethoxy)silane, γ-methoxypropyltrimethoxysilane, β-(3,4-ethoxycyclohexyl)ethyltrimethoxysilane, γ-mercaptopropyltrimethoxysilane, or the like.

The silane coupling agent may be contained in an amount of 5 parts by weight or less based on 100 parts by weight of the ethylene-vinyl acetate copolymer. Specifically, the silane coupling agent may be contained in an amount of 0.1 to 5 parts by weight, 0.1 to 3 parts by weight, or 0.1 to 2 parts by weight, based on 100 parts by weight of the ethylene-vinyl acetate copolymer.

The quinone-based compound serves to improve the stability of the ethylene-vinyl acetate copolymer. The quinone-based compound may be, for example, hydroquinone, hydroquinone methyl ethyl, p-benzoquinone, methylhydroquinone, or the like. Further, the quinone-based compound may be contained in an amount of 5 parts by weight or less based on 100 parts by weight of the ethylene-vinyl acetate copolymer. Specifically, the quinone-based compound may be contained in an amount of 0.1 to 5 parts by weight based on 100 parts by weight of the ethylene-vinyl acetate copolymer.

The ultraviolet absorber may be, for example, a benzophenone compound such as 2-hydroxy-4-octoxybenzophenone, 2-hydroxy-4-methoxy-5-sulfonebenzophenone, and the like; a benzotriazole compound such as 2-(2′-hydroxy-5-methylphenyl)benzotriazole and the like; and a salicylate compound such as phenyl salicylate, p-t-butylphenyl salicylate, and the like.

The antioxidant may be, for example, an amine-based, phenol-based, or bisphenyl-based antioxidant. Specifically, the antioxidant may be t-butyl-p-cresol, bis-(2,2,6,6-tetramethyl-4-piperazyl) sebacate, or the like.

Encapsulant for Solar Cells

The encapsulant for solar cells may be prepared by extruding an encapsulant composition comprising an ethylene-vinyl acetate copolymer and magnesium oxide into an uncured or semi-cured sheet.

The encapsulant for solar cells is applied to a solar cell module and then cured to perform the encapsulation function. The volume resistivity and the haze of an encapsulant for solar cells to be described below are those measured after the encapsulant for solar cells is cured.

The encapsulant for solar cells may have a volume resistivity of 1×10¹⁵ to 1×10¹⁷ Ω·cm or 1×10¹⁶ to 1×10¹⁷ Ω·cm measured at a voltage of 1,000 V at 25° C. Specifically, the encapsulant for solar cells may have a volume resistivity of 1×10¹⁶ to 5×10¹⁶ Ω·cm, 1×10¹⁶ to 4×10¹⁶ Ω·cm, or 1×10¹⁶ to 3×10¹⁶ Ω·cm measured at a voltage of 1,000 V at 25° C.

The encapsulant for solar cells may have a volume resistivity of 1×10¹⁵ Ω·cm or more measured at a voltage of 1,000 V after being left for 72 hours at a relative humidity of 100% and 120° C. Specifically, the encapsulant for solar cells may have a volume resistivity of 1×10¹⁵ to 1×10¹⁷ Ω·cm, 1×10¹⁵ to 1×10¹⁶ Ω·cm, 1×10¹⁵ to 8×10¹⁵ Ω·cm, or 1×10¹⁵ to 5×10¹⁵ Ω·cm measured at a voltage of 1,000 V after being left for 72 hours at a relative humidity of 100% and 120° C. In particular, if the volume resistivity of an encapsulant for solar cells is less than 1×10¹⁵ Ω·cm, there may be a problem that the resistance to wet leakage of the encapsulant deteriorates.

However, since the encapsulant for solar cells of an embodiment is excellent in moisture resistance, it has a volume resistivity of 1×10¹⁵ Ω·cm or more, thereby producing the effect that the electric resistance of the encapsulant does not deteriorate, even after being left for 72 hours under the conditions of 120° C. and a relative humidity of 100%.

The encapsulant for solar cells may have an average haze of 2 to 8% measured at 25° C. on samples obtained by cutting the encapsulant having a size of 1,000 mm×200 mm×0.5 mm (width×length×thickness) into a size of 100 mm×100 mm (width×length), wherein the standard deviation of haze of the samples may be 0.1 to 0.5%. Specifically, the encapsulant for solar cells may have an average haze of 3 to 8%, 4 to 7%, or 5 to 6% measured at 25° C. on samples obtained by cutting the encapsulant having a size of 1,000 mm×200 mm×0.5 mm (width×length×thickness) into a size of 100 mm×100 mm (width×length), wherein the standard deviation of haze of the samples may be 0.1 to 0.4% or 0.1 to 0.3%.

The encapsulant for solar cells may have an initiation time for curing reaction of 3 minutes or less measured at 150° C. with a rheometer. Specifically, the encapsulant for solar cells may have an initiation time for curing reaction of 1 to 3 minutes measured at 150° C. with a rheometer.

The encapsulant for solar cells may have an average thickness of 200 to 800 μm. Specifically, the encapsulant for solar cells may have an average thickness of 300 to 700 μM.

Solar Cell Module

According to an embodiment, there is provided a solar cell module, which comprises a transparent protective substrate, a first encapsulant sheet, at least one solar cell connected to an electrode, a second encapsulant sheet, and a back sheet, all of which are laminated in this order, wherein at least one of the first encapsulant sheet and the second encapsulant sheet comprises an ethylene-vinyl acetate copolymer and magnesium oxide, and the magnesium oxide is contained in an amount of 0.001 to 0.20 parts by weight based on 100 parts by weight of the ethylene-vinyl acetate copolymer and has a specific surface area of 50 to 200 m²/g.

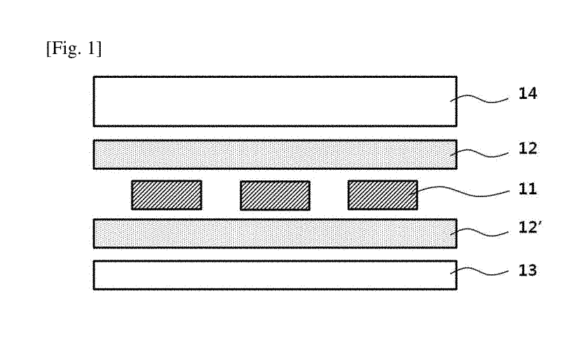

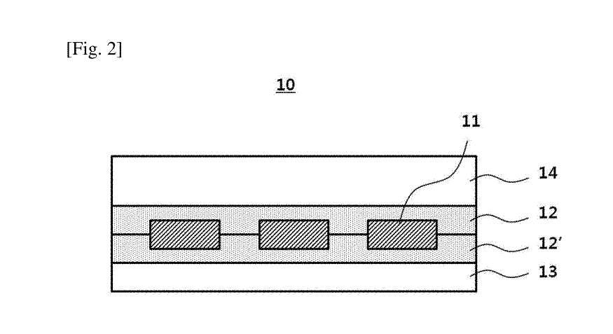

FIGS. 1 and 2 schematically illustrate the configurations (i.e., an exploded view and an assembled view, respectively) of a solar cell module. The solar cell module (10) comprises a transparent protective substrate (14), a first encapsulant sheet (12), at least one solar cell (11) connected to an electrode, a second encapsulant sheet (12′), and a back sheet (13), all of which are laminated in this order. At least one of the first encapsulant sheet (12) and the second encapsulant sheet (12′) comprises an ethylene-vinyl acetate copolymer and magnesium oxide.

The solar cell module (10) may be prepared by laminating the constituent layers inclusive of the solar cell (11) and the encapsulant sheets (12 and 12′) in order and then processing (e.g., heating and pressing) them. Here, at least one of the first encapsulant sheet (12) and the second encapsulant sheet (12′) may adopt the encapsulant for solar cells as described above.

The solar cell (11), the back sheet (13), and the transparent protective substrate (14) that constitute the solar cell module (10) may be appropriately selected from those conventionally used. In particular, both of the transparent protective substrate and the back sheet may be glass substrates.

The solar cell module may have a reduction in the power output of 5% or less after being left for 3,000 hours at a relative humidity of 85% at 85° C. Specifically, the solar cell module may have a reduction in the power output of 0.1 to 5%, 1 to 5%, 2 to 5%, 2 to 4.8%, or 2.5 to 3% measured after being left for 3,000 hours at a relative humidity of 85% at 85° C.

Process for Preparing an Encapsulant for Solar Cells

According to another embodiment, there is provided a process for preparing an encapsulant for solar cells, which comprises (1) mixing an ethylene-vinyl acetate copolymer and magnesium oxide to prepare a masterbatch; (2) mixing the masterbatch with an ethylene-vinyl acetate copolymer to prepare an encapsulant composition; and (3) melt-extruding the encapsulant composition, wherein the magnesium oxide is contained in the encapsulant composition in an amount of 0.001 to 0.20 parts by weight per 100 parts by weight of the ethylene-vinyl acetate copolymer and has a specific surface area of 50 to 200 m²/g.

Step (1)

In this step, an ethylene-vinyl acetate copolymer and magnesium oxide are mixed to prepare a masterbatch.

The ethylene-vinyl acetate copolymer and the magnesium oxide are as described with regard to the encapsulant for solar cells.

The masterbatch may comprise 0.3 to 5 parts by weight of magnesium oxide based on 100 parts by weight of the ethylene-vinyl acetate copolymer. Specifically, the masterbatch may comprise 0.3 to 4 parts by weight, 0.3 to 3 parts by weight, or 0.4 to 1 part by weight of magnesium oxide based on 100 parts by weight of the ethylene-vinyl acetate copolymer.

The mixing in this step may be carried out at 80 to 160° C. Specifically, the mixing in this step may be carried out at 80 to 150° C., 100 to 140° C., or 120 to 140° C.

Step (2)

In this step, the masterbatch is mixed with an ethylene-vinyl acetate copolymer to prepare an encapsulant composition.

The mixing ratio of the masterbatch to the ethylene-vinyl acetate copolymer may be 1:5 to 1:100 by weight. Specifically, the mixing ratio of the masterbatch to the ethylene-vinyl acetate copolymer may be 1:5 to 1:50, 1:5 to 1:30, or 1:5 to 1:20 by weight.

As the content of magnesium oxide contained in the masterbatch increases, the feeding rate of the ethylene-vinyl acetate copolymer relative to the masterbatch may be increased. In addition, the mixing ratio of the masterbatch to the ethylene-vinyl acetate copolymer may be controlled by the ratio of the feeding rate of the masterbatch to that of the ethylene-vinyl acetate copolymer.

The mixing in this step may be carried out at 70 to 120° C. Specifically, the mixing in this step may be carried out at 75 to 120° C., 75 to 100° C., or 75 to 95° C.

### Example

Hereinafter, the present invention is explained in detail by the following Examples. However, the following Examples are intended to further illustrate the present invention. The scope of the present invention is not limited thereto only.

The components used in the Examples and the Comparative Examples below are as follows.
Ethylene-Vinyl Acetate Copolymer: containing 28% by weight of vinyl acetate with a weight average molecular weight of 54,000 g/mole and a melt flow rate (MFR) of 15 g/10 min at 190° C. under a load of 2.16 kg.
Crosslinking agent: Luperox TBEC (t-butylperoxy-2-ethylhexylcarbonate) from Arkema.
Crosslinking aid: TAICROS (triallyl isocyanurate) from Evonik.
Magnesium oxide A: Specific surface area 100 m²/g.
Magnesium oxide B: Specific surface area 150 m²/g.
Magnesium oxide C: Specific surface area 200 m²/g.
Magnesium oxide D: Specific surface area 30 m²/g.
Magnesium oxide E: Specific surface area 250 m²/g.

### Example 1: Preparation of an Encapsulant

0.01 part by weight of magnesium oxide A was compounded with 100 parts by weight of the ethylene-vinyl acetate copolymer to prepare a mixture. Then, 1.0 part by weight of the crosslinking agent and 1.0 part by weight of the crosslinking aid were compounded therewith to prepare an encapsulant composition.

The encapsulant composition was subjected to a T-die extrusion step at 100° C. to prepare an encapsulant having a thickness of 500 μm.

### Examples 2 to 9 and Comparative Examples 1 to 4

Each encapsulant was prepared in the same manner as in Example 1, except that the kind and content of magnesium oxide were changed as shown in Table 1 below.

### Example 10

0.5 part by weight of magnesium oxide B was compounded with 100 parts by weight of the ethylene-vinyl acetate copolymer at 130° C. to prepare a masterbatch. The masterbatch and the ethylene-vinyl acetate copolymer were fed and mixed at a ratio of 1:10 by weight at 85° C. to prepare a mixture. Then, 1.0 part by weight of the crosslinking agent and 1.0 part by weight of the crosslinking aid were added thereto, followed by mixing thereof, to prepare an encapsulant composition.

The encapsulant composition was subjected to a T-die extrusion step at 100° C. to prepare an encapsulant having a thickness of 500 μm.

TABLE 1

| | Ethylene- | | | | | | | |
|---|---|---|---|---|---|---|---|---|
| Component | vinyl acetate | Crosslinking | Crosslinking | | | | | |
| (wt. %) | copolymer | agent | aid | MgO A | MgO B | MgO C | MgO D | MgO E |
| Ex. 1 | 100 | 1 | 1 | 0.01 | — | — | — | — |
| Ex. 2 | 100 | 1 | 1 | 0.05 | — | — | — | — |
| Ex. 3 | 100 | 1 | 1 | 0.2 | — | — | — | — |
| Ex. 4 | 100 | 1 | 1 | — | 0.01 | — | — | — |
| Ex. 5 | 100 | 1 | 1 | — | 0.05 | — | — | — |
| Ex. 6 | 100 | 1 | 1 | — | 0.2 | — | — | — |
| Ex. 7 | 100 | 1 | 1 | — | — | 0.01 | — | — |
| Ex. 8 | 100 | 1 | 1 | — | — | 0.05 | — | — |
| Ex. 9 | 100 | 1 | 1 | — | — | 0.2 | — | — |
| Ex. 10 | 100 | 1 | 1 | — | 0.05 | — | — | — |
| C. Ex. 1 | 100 | 1 | 1 | — | — | — | — | — |
| C. Ex. 2 | 100 | 1 | 1 | — | 0.22 | — | — | — |
| C. Ex. 3 | 100 | 1 | 1 | — | — | — | 0.1 | — |
| C. Ex. 4 | 100 | 1 | 1 | — | — | — | — | 0.1 |

### Test Example

The properties of the encapsulants of Examples 1 to 10 and Comparative Examples 1 to 4 were measured by the following methods, and the results are shown in Tables 2 to 4 below.

(1) Volume Resistivity

The encapsulant was heated at 1 atm and 150° C. for 15 minutes using a vacuum laminator (NPC), and the initial volume resistivity was measured at 25° C. according to ASTM D257. At this time, a voltage of 1,000 V was applied for 120 seconds.

Thereafter, the change in the volume resistivity was measured after the encapsulant had been left in a pressure cooker test chamber for 72 hours at 120° C. at a relative humidity of 100%.

(2) Haze

The encapsulant was cut into a size of 50 mm×50 mm×0.5 mm (width×length× thickness) to prepare a sample, and the haze thereof was measured at 25° C. according to ASTM D1003.

(3) Initiation Time for Curing Reaction (Ts1)

The encapsulant was measured for the initiation time for curing reaction at 150° C. using a rheometer.

(4) Preparation of a Solar Cell Module and Evaluation of a Reduction in the Power Output

Glass/encapsulant/solar cell (manufacturer: JSPV, brand name: JSCM3186)/encapsulant/glass were laminated in this order (i.e., a structure of G (glass) to G (glass)) to produce a solar cell module. The encapsulants prepared in Examples 1 to 10 and Comparative Examples 1 to 4 were each used here.

The solar cell module had a size of 200 mm×200 mm (width×length) in which one solar cell was employed. The lamination was carried out at a temperature of 160° C. for 5 minutes under vacuum and for 20 minutes at 1 atm using a 50×50 laminator manufactured by NPC to prepare the solar cell module.

The initial power output of the solar cell module was measured using a solar simulator falling under Class A according to JIS C8912, in which a xenon lamp was used as a light source. The power output was measured in the same manner as described above after the solar cell module was left for 3,000 hours at 85° C. and a relative humidity of 85% (i.e., a damp heat test). Then, the reduction in the power output was calculated in percent after the damp heat test relative to the initial power output.

TABLE 2

| | | | Volume resistivity | Reduction in |
|---|---|---|---|---|
| | | Initial | after 72 hours at | the power output |
| | | volume | 120° C. and a | after 3,000 hours |
| | Haze | resistivity | relative humidity of | at 85° C. and a relative |
| | (%) | (Ω · cm) | 100% (Ω · cm) | humidity of 85% (%) |
| C. Ex. 1 | 2.1 | 5.1 × 10¹⁵ | 3.2 × 10¹⁵ | 13% |
| C. Ex. 2 | 10.5 | 4.6 × 10¹⁵ | 2.5 × 10¹⁵ | 3.2% |
| Ex. 1 | 3.7 | 6.1 × 10¹⁵ | 1.8 × 10¹⁵ | 4.1% |
| Ex. 2 | 4.8 | 3.1 × 10¹⁵ | 2.1 × 10¹⁵ | 2.9% |
| Ex. 3 | 7.6 | 6.5 × 10¹⁵ | 2.5 × 10¹⁵ | 3.4% |
| Ex. 4 | 2.9 | 5.3 × 10¹⁵ | 1.9 × 10¹⁵ | 4.7% |
| Ex. 5 | 4.1 | 3.9 × 10¹⁵ | 2.1 × 10¹⁵ | 2.9% |
| Ex. 6 | 7.8 | 6.3 × 10¹⁵ | 3.2 × 10¹⁵ | 2.9% |
| Ex. 7 | 3.2 | 6.4 × 10¹⁵ | 2.5 × 10¹⁵ | 3.5% |
| Ex. 8 | 4.9 | 5.3 × 10¹⁵ | 1.8 × 10¹⁵ | 2.9% |
| Ex. 9 | 7.6 | 4.9 × 10¹⁵ | 2.1 × 10¹⁵ | 2.5% |
| Ex. 10 | 5.6 | 2.1 × 10¹⁶ | 3.1 × 10¹⁵ | — |

TABLE 3

| | | Reduction in the power |
|---|---|---|
| | | output after 3,000 hours at 85° C. |
| | ts1 | and a relative humidity of 85% |
| C. Ex. 1 | 2 minutes 50 seconds | 13% |
| C. Ex. 2 | 3 minutes 5 seconds | 3.2% |
| C. Ex. 3 | 2 minutes 51 seconds | 7.9% |
| C. Ex. 4 | 3 minutes 25 seconds | 2.3% |
| Ex. 2 | 2 minutes 59 seconds | 2.9% |
| Ex. 5 | 2 minutes 57 seconds | 2.9% |
| Ex. 8 | 3 minutes 00 seconds | 2.9% |

As shown in Tables 2 and 3, the encapsulants of Examples 1 to 10 had an initial volume resistivity of 1×10¹⁵ Ω·cm or more, a haze of 8% or less, and a volume resistivity of 1×10¹⁵ Ω·cm or more after the pressure cooker test. The reduction in the power output thereof was less than 5% after the encapsulants had been left for 3,000 hours at 85° C. and a relative humidity of 85%. Especially, the encapsulant of Example 10 had a very high initial volume resistivity of 2.1×10¹⁶ Ω·cm.

In contrast, the encapsulant of Comparative Example 1 containing no magnesium oxide had a large reduction in the power output after being left under the harsh conditions, and the encapsulant of Comparative Example 2 containing an excessive amount of magnesium oxide had a high haze. Thus, they are not suitable for solar cells.

(5) Standard Deviation of Haze

The encapsulant of Example 10 was cut into a size of 1,000 mm×200 mm×0.5 mm (width×length×thickness), which was then cut into a size of 100 mm×100 mm (width×length) to prepare 20 samples. Then, the haze of each sample was measured at 25° C. according to ASTM D1003, and the average haze and the standard deviation of the 20 samples were calculated.

TABLE 4

| Sample | Haze (%) |
|---|---|
| 1 | 5.61 |
| 2 | 5.91 |
| 3 | 5.41 |
| 4 | 5.85 |
| 5 | 5.3 |
| 6 | 5.87 |
| 7 | 5.9 |
| 8 | 5.37 |
| 9 | 5.72 |
| 10 | 5.39 |
| 11 | 5.73 |
| 12 | 5.71 |
| 13 | 5.63 |
| 14 | 5.77 |
| 15 | 5.41 |
| 16 | 5.59 |
| 17 | 5.62 |
| 18 | 5.31 |
| 19 | 5.59 |
| 20 | 5.32 |

The average haze of the samples of the encapsulant of Example 10 was 5.6%, and the standard deviation of haze was 0.207%, indicating a very uniform distribution.

### DESCRIPTION OF THE NUMERALS

10: solar cell module
11: solar cell
12: first encapsulant sheet
12′: second encapsulant sheet
13: back sheet
14: transparent protective substrate

1. An encapsulant for solar cells, which comprises: an ethylene-vinyl acetate copolymer and magnesium oxide,
wherein the magnesium oxide is contained in an amount of 0.001 to 0.20 parts by weight based on 100 parts by weight of the ethylene-vinyl acetate copolymer and has a specific surface area of 50 to 200 m²/g.

2. The encapsulant for solar cells of claim 1, which has a volume resistivity of 1×10¹⁵ to 1×10¹⁷ Ω·cm measured at a voltage of 1,000 V at 25° C.

3. The encapsulant for solar cells of claim 1, which has a volume resistivity of 1×10¹⁵ to 1×10¹⁷ Ω·cm measured at a voltage of 1,000 V after being left for 72 hours at a relative humidity of 100% and 120° C.

4. The encapsulant for solar cells of claim 1, which has an initiation time for curing reaction of 3 minutes or less measured at 150° C. with a rheometer.

5. The encapsulant for solar cells of claim 1, which has an average haze of 2 to 8% measured at 25° C. on samples obtained by cutting the encapsulant having a size of 1,000 mm×200 mm×0.5 mm (width×length×thickness) into a size of 100 mm×100 mm (width×length), wherein the standard deviation of haze of the samples is 0.1 to 0.5%.

6. The encapsulant for solar cells of claim 1, which comprises a crosslinking aid, wherein the crosslinking aid is contained in an amount of 0.1 to 10 parts by weight based on 100 parts by weight of the ethylene-vinyl acetate copolymer.

7. The encapsulant for solar cells of claim 1, which comprises an organic peroxide as a crosslinking agent, wherein the crosslinking agent is contained in an amount of 0.3 to 5 parts by weight based on 100 parts by weight of the ethylene-vinyl acetate copolymer.

8. A solar cell module, which comprises: a transparent protective substrate, a first encapsulant sheet, at least one solar cell connected to an electrode, a second encapsulant sheet, and a back sheet, all of which are laminated in this order,
wherein at least one of the first encapsulant sheet and the second encapsulant sheet comprises an ethylene-vinyl acetate copolymer and magnesium oxide, and
the magnesium oxide is contained in an amount of 0.001 to 0.20 parts by weight based on 100 parts by weight of the ethylene-vinyl acetate copolymer and has a specific surface area of 50 to 200 m²/g.

9. The solar cell module of claim 8, which has a reduction in the power output of 5% or less after being left for 3,000 hours at a relative humidity of 85% at 85° C.

10. A process for preparing an encapsulant for solar cells, which comprises:
(1) mixing an ethylene-vinyl acetate copolymer and magnesium oxide to prepare a masterbatch;
(2) mixing the masterbatch with an ethylene-vinyl acetate copolymer to prepare an encapsulant composition; and
(3) melt-extruding the encapsulant composition,
wherein the magnesium oxide is contained in the encapsulant composition in an amount of 0.001 to 0.20 parts by weight per 100 parts by weight of the ethylene-vinyl acetate copolymer and has a specific surface area of 50 to 200 m²/g.

11. The process for preparing an encapsulant for solar cells of claim 10, wherein the masterbatch comprises 0.3 to 5 parts by weight of magnesium oxide based on 100 parts by weight of the ethylene-vinyl acetate copolymer.

12. The process for preparing an encapsulant for solar cells of claim 10, wherein the mixing ratio of the masterbatch to the ethylene-vinyl acetate copolymer is 1:5 to 1:100 by weight.

13. The process for preparing an encapsulant for solar cells of claim 10, wherein the mixing in the step (1) is carried out at 80 to 160° C., and the mixing in the step (2) is carried out at 70 to 120° C.
